(19) United States
(12) Patent Application Publication
(10) Pub. No.: US 2012/0292604 A1
(43) Pub. Date: Nov. 22, 2012

(54) ORGANIC LIGHT EMITTING DEVICE

(75) Inventor: Meng-Ting Lee, Taipei City (TW)

(73) Assignee: AU OPTRONICS CORPORATION, Hsinchu (TW)

(21) Appl. No.: 13/190,495

(22) Filed: Jul. 26, 2011

(30) Foreign Application Priority Data
May 19, 2011 (TW) 100117611

(51) Int. Cl. H01L 51/30

(52) U.S. Cl. 257/40; 257/E51.026

(57) ABSTRACT

An organic light emitting device is provided. The organic light emitting device includes a substrate, at least one organic scattering layer, a first electrode layer, an organic light emitting layer, and a second electrode layer. The organic scattering layer is disposed on a surface of the substrate, and a glass transition temperature Tg of a material of the organic scattering layer is lower than 150° C. The first electrode layer is disposed on the substrate. The organic light emitting layer is disposed on the first electrode layer. The second electrode layer is disposed on the organic light emitting layer.

### CROSS-REFERENCE TO RELATED APPLICATION

This application claims the priority benefit of Taiwan application serial no. 100117611, filed on May 19, 2011. The entirety of the above-mentioned patent application is hereby incorporated by reference herein and made a part of this specification.

### BACKGROUND OF THE INVENTION

1. Field of the Invention

The invention relates to an organic light emitting device, and more particularly to an organic light emitting device having superior light extraction efficiency.

2. Description of Related Art

The information and communication industries have become indispensable in our society thanks to the focused development of various portable communication and display products. As the flat panel display is one of the communication interfaces between human and an information device, development of the flat panel display is rather essential. The organic light emitting device has tremendous application potential to become the mainstream of the next generation flat panel display due to its advantages of self-luminescence, wide viewing angle, low power consumption, simple manufacturing process, low cost, low working temperature, high response speed, full-color display, and so forth.

Generally, the organic light emitting device includes a first electrode layer disposed on a substrate, a second electrode layer, and an organic light emitting layer sandwiched between the two electrode layers. The substrate and the first electrode layer are often made of a light transmissive material, such that light generated by the organic light emitting layer can be emitted. A refractive index of the first electrode layer is 1.9 approximately, a refractive index of the substrate is 1.4 approximately, and a refractive index of the air is 1. It is known that a total reflection is likely to occur at the interface between a material with high refractive index and a material with low refractive index. Thus, when a light emitted from the organic light emitting layer is transmitted from the first electrode layer to the substrate and from the substrate to the air, a total reflection may occur at these interfaces, thereby lowering the light extraction efficiency of the organic light emitting device. For example, almost 30% of light is totally reflected at the interface when the light is transmitted from the first electrode layer to the substrate, and similarly, almost 30% of light is totally reflected at the interface when the light is transmitted from the substrate to the air. Therefore, the light extraction efficiency of the organic light emitting device simply reaches 15% to 20% approximately.

### SUMMARY OF THE INVENTION

The invention provides an organic light emitting device having superior light extraction efficiency.

An organic light emitting device is provided. The organic light emitting device includes a substrate, at least one organic scattering layer, a first electrode layer, an organic light emitting layer, and a second electrode layer. The organic scattering layer is disposed on a surface of the substrate, and a glass transition temperature Tg of a material of the organic scattering layer is lower than 150° C. The first electrode layer is disposed on the substrate. The organic light emitting layer is disposed on the first electrode layer. The second electrode layer is disposed on the organic light emitting layer.

Based on the above, the organic light emitting device of the invention includes the organic scattering layer disposed on a surface of the substrate. Accordingly, the light is prevented from being total reflected at the interface between the electrode layer and the substrate or between the substrate and the air. Therefore, the light extraction efficiency of the organic light emitting device is greatly increased.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1D are schematic cross-sectional views of a fabricating process of an organic light emitting device according to an embodiment of the invention.

FIGS. 2A to 2D are schematic cross-sectional views of a fabricating process of an organic light emitting device according to another embodiment of the invention.

FIG. 3 is a schematic cross-sectional view showing an organic light emitting device according to still another embodiment of the invention.

### DESCRIPTION OF EMBODIMENTS

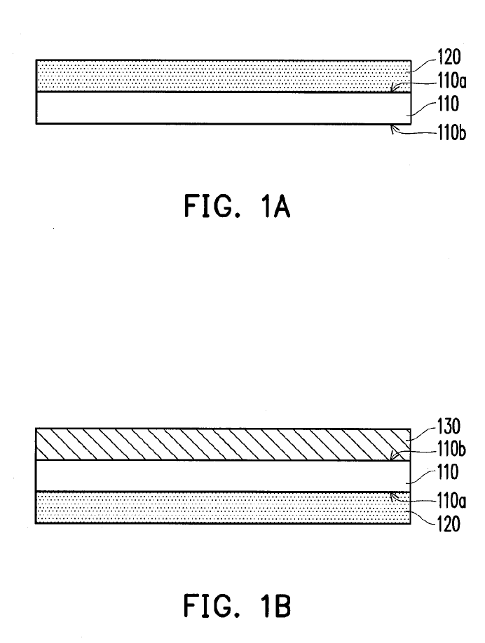

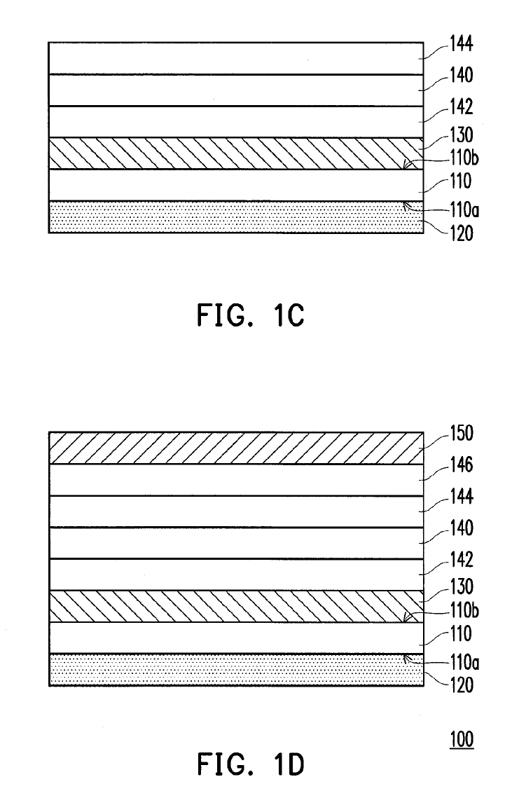

FIGS. 1A to 1D are schematic cross-sectional views of a fabricating process of an organic light emitting device according to an embodiment of the invention. Referring to FIG. 1A, first, an organic scattering layer 120 is formed on a first surface 110a of a substrate 110, wherein a glass transition temperature Tg of a material of the organic scattering layer 120 is lower than 150° C. According to the present embodiment, the substrate 110 has a first surface 110a and a second surface 110b which are opposite to each other. A method of forming the organic scattering layer 120 includes forming an organic scattering material layer (not shown) on the first surface 110a of the substrate 110, and then performing an annealing process on the organic scattering material layer. A method of forming the organic scattering material layer includes a vacuum evaporation process, a coating process or other suitable methods. The coating process includes, for example, dissolving organic materials in the organic solvent such as methanol, and then coating the formed solution onto the first surface 110a of the substrate 110 by dropping. The temperature of the annealing process is, for example, higher than the glass transition temperature Tg of the material of the organic scattering layer 120 such as from 80° C. to 200° C., and preferably 150° C.

According to the present embodiment, the substrate 110 can be made of light-transmissive materials (such as glass, quartz or an organic polymer) or other suitable materials, and the refractive index thereof is larger than 1.4. The glass transition temperature Tg of the organic scattering layer 120 is preferably lower than 150° C., so as to prevent crystallization. The absorption wavelength of the material of the organic scattering layer 120 is, for example, smaller than 400 nm, so as to prevent the visible light from being absorbed by the organic scattering layer 120. Accordingly, light loss can be reduced. For example, the material of the organic scattering layer 120 can be phenanthroline, and the material of the organic scattering layer 120 preferably has a structure represented by Formula 1, wherein Z in Formula 1 is selected from the group consisting of Formula 2 to Formula 7.

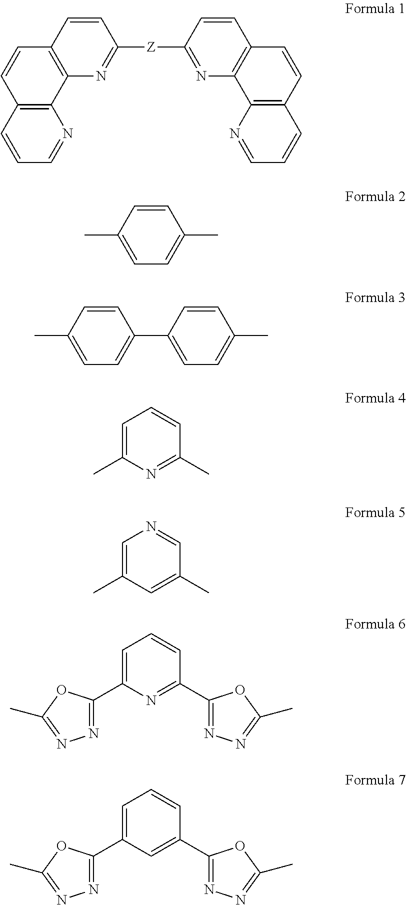

According to an embodiment, the material of the organic scattering layer 120 is, for example, 4,7-diphenyl-1,10-phenanthroline (Bphen) or 2,9-dimethyl-4,7-diphenyl-1,10-phenanthroline (BCP).

Referring to FIG. 1B, a first electrode layer 130 is then formed on the second surface 110b of the substrate 110. According to the present embodiment, a method of forming the first electrode layer 130 includes a sputtering process. A material of the first electrode layer 130 is, for example, a transparent conductive material. The transparent conductive material includes metal oxide, such as indium tin oxide (ITO), indium zinc oxide (IZO), aluminum tin oxide (ATO), aluminum zinc oxide (AZO), indium germanium zinc oxide (IGZO), other suitable oxide, or a stacked layer having at least two of the above materials. According to the present embodiment, a refractive index of the first electrode layer 130 is, for example, higher than a refractive index of the substrate 110. The refractive index of the first electrode layer 130 is about 1.9, for example.

Referring to FIG. 1C, thereafter, an organic light emitting layer 140 is formed on the first electrode layer 130. According to the present embodiment, a hole transport layer 142 is further formed between the first electrode layer 130 and the organic light emitting layer 140, thereby increasing the light extraction efficiency of the light emitting device. In other words, this step includes forming the hole transport layer 142 on the first electrode layer 130, and then forming the organic light emitting layer 140 on the hole transport layer 142. A method of forming the organic light emitting layer 140 is, for example, a vacuum evaporation process. The organic light emitting layer 140 can be a red organic light emitting pattern, a green organic light emitting pattern, a blue organic light emitting pattern, organic light emitting patterns of other color, or a combination thereof. A method of forming the hole transport layer 142 is, for example, a vacuum evaporation process. It should be noted that, in another embodiment (not shown), a hole injection layer can be further disposed between the first electrode layer 130 and the hole transport layer 142. However, the disposition of the hole transport layer 142 and the hole injection layer is optional, in other words, the forming of the hole transport layer 142 and the hole injection layer can be omitted.

Referring to FIG. 1D, then, a second electrode layer 150 is formed on the organic light emitting layer 140. According to the present embodiment, in order to further increase the light extraction efficiency of the organic light emitting device, an electron transport layer 144 and an electron injection layer 146 are formed between the organic light emitting layer 140 and the second electrode layer 150. In other words, this step includes sequentially forming the electron transport layer 144 and the electron injection layer 146 on the organic light emitting layer 140, and then forming the second electrode layer 150 on the hole transport layer 146. A method of forming the second electrode layer 150 is, for example, a sputtering process. A material of the second electrode layer 150 is, for example, a transparent conductive material or a non-transparent conductive material. The transparent conductive material can refer to those described above, and the non-transparent conductive material can be metals. A method of forming the electron transport layer 144 and the electron injection layer 146 is, for example, a vacuum evaporation process. It is noted that the disposition of the hole transport layer 144 and the hole injection layer 146 is optional, in other words, the forming of the hole transport layer 144 and the hole injection layer 146 can be omitted. According to the present embodiment, after forming the second electrode 150, the fabricating process of the organic light emitting device 100 is generally completed.

As shown in FIG. 1D, the organic light emitting device 100 includes the substrate 110, the organic scattering layer 120, the first electrode layer 130, the organic light emitting layer 140, and the second electrode layer 150. The organic scattering layer 120 is disposed on the first surface 110a of the substrate 110, and the glass transition temperature Tg of the material of the organic scattering layer 120 is lower than 150° C. The first electrode layer 130 is disposed on the second surface 110b of the substrate 110. According to the present embodiment, the first surface 110a and the second surface 110b are opposite surfaces, wherein the first surface 110a is, for example, a lower surface and near the light emitting surface of the organic light emitting device 100, and the second surface 110b is, for example, an upper surface and away from the light emitting surface of the organic light emitting device 100. In other words, according to the present embodiment, the organic scattering layer 120 and the first electrode layer 130 are, for example, disposed on the opposite sides of the substrate 110, and thus the substrate 110 is, for example, disposed between the organic scattering layer 120 and the first electrode layer 130. According to the present embodiment, the organic scattering layer 120 contacts the substrate 110, for example.

The organic light emitting layer 140 is disposed on the first electrode layer 130. The second electrode layer 150 is disposed on the organic light emitting layer 140. According to the present embodiment, the organic light emitting device 100 further includes the hole transport layer 142, the electron transport layer 144, and the electron injection layer 146. The hole transport layer 142 is disposed between the first electrode layer 130 and the organic light emitting layer 140. According to an embodiment, a hole injection layer can be further disposed between the first electrode layer 130 and the hole transport layer 142. The electron injection layer 146 and the electron transport layer 144 are, for example, disposed between the second electrode layer 150 and the organic light emitting layer 140, and the electron transport layer 144 is, for example, disposed between the electron injection layer 146 and the organic light emitting layer 140. However, it is noted that the disposition of the hole injection layer, the hole transport layer 142, the electron transport layer 144, and the electron injection layer 146 is optional, in other words, these layers may be not disposed in the organic light emitting device 100.

Generally, in the organic light emitting device, as the refractive index of the substrate is usually higher than the refractive index of the air, the light emitted from the organic light emitting layer is likely to be totally reflected at the interface between the substrate and the air. According to the present embodiment, the organic scattering layer 120 is formed between the substrate 110 and the air, that is, the organic scattering layer 120 is sandwiched between the substrate 110 and the air. As such, the light emitted from the organic light emitting layer 140 at a wide angle can be prevented from being totally reflected at the interface between the substrate 110 and the air, so as to greatly increase the light extraction efficiency of the organic light emitting device 100.

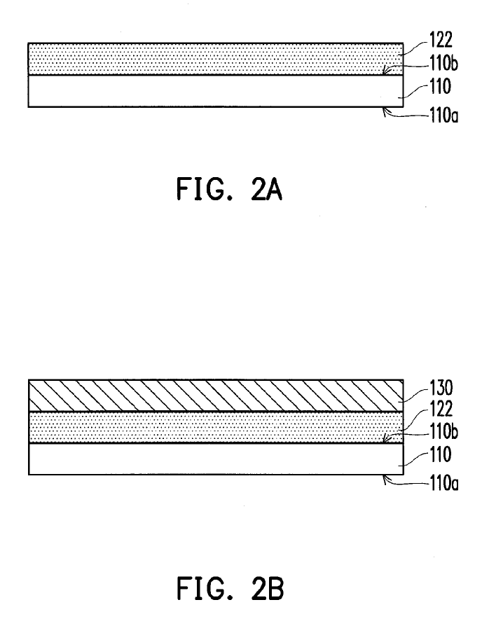

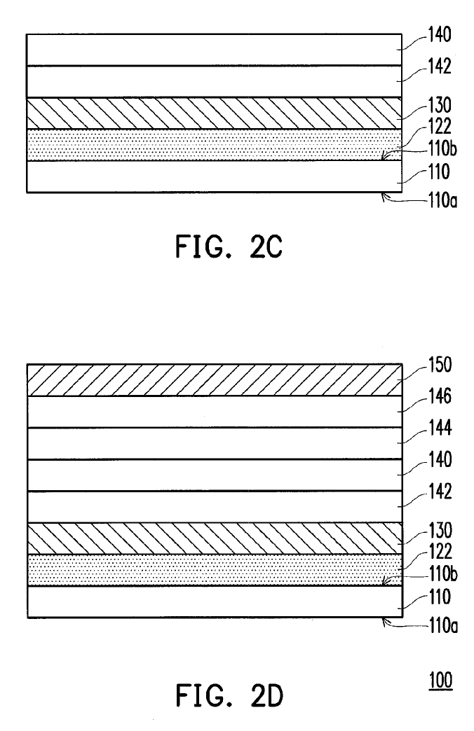

FIGS. 2A to 2D are schematic cross-sectional views of a fabricating process of an organic light emitting device according to another embodiment of the invention. Referring to FIG. 2A, first, an organic scattering layer 122 is formed on a second surface 110b of a substrate 110, wherein a glass transition temperature Tg of a material of the organic scattering layer 122 is lower than 150° C. According to the present embodiment, the substrate 110 has a first surface 110a and a second surface 110b which are opposite to each other. A material of the substrate 110 and a material and a forming method of the organic scattering layer 122 can refer to those provided in the previous embodiment, and thus further descriptions are omitted.

Referring to FIG. 2B, then, a first electrode layer 130 is formed on the organic scattering layer 122. In other words, according to the present embodiment, the organic scattering layer 122 and the first electrode 130 are, for example, sequentially stacked on a second surface 110b of the substrate 110. A refractive index of the first electrode layer 130 is, for example, higher than a refractive index of the substrate 110. A material and a forming method of the first electrode layer 130 can refer to those provided in the previous embodiment, and thus further descriptions are omitted.

Referring to FIG. 2C, thereafter, a hole transport layer 142 and an organic light emitting layer 140 are sequentially formed on the first electrode layer 130. This step can refer to those provided in the previous embodiment, and thus further descriptions are omitted. It is noted that a hole injection layer can be further disposed between the first electrode layer 130 and the hole transport layer 142. However, the disposition of the hole transport layer 142 and the hole injection layer is optional, in other words, the forming of the hole transport layer 142 and the hole injection layer can be omitted.

Referring to FIG. 2D, then, an electron transport layer 144, an electron injection layer 146 and the second electrode layer 150 are formed on the organic light emitting layer 140. This step can refer to those provided in the previous embodiment, and thus further descriptions are omitted. It is noted that the disposition of the electron transport layer 144 and the electron injection layer 146 is optional, in other words, the forming of the electron transport layer 144 and the electron injection layer 146 can be omitted. According to the present embodiment, after forming the second electrode 150, the fabricating process of the organic light emitting device 100 is generally completed.

The organic light emitting device 100 includes the substrate 110, the organic scattering layer 122, the first electrode layer 130, the organic light emitting layer 140, and the second electrode layer 150. The organic scattering layer 122 is disposed on the second surface 110b of the substrate 110, and the glass transition temperature Tg of the material of the organic scattering layer 122 is lower than 150° C. In the present embodiment, the first surface 110a and the second surface 110b are opposite surfaces, wherein the first surface 110a is, for example, a lower surface, contacting the air, and substantially the light emitting surface of the organic light emitting device 100, and the second surface 110b is, for example, an upper surface. The first electrode layer 130 is disposed on the organic light emitting layer 122. According to the present embodiment, the organic scattering layer 122 and the first electrode 130 are, for example, disposed at the same side of the substrate 110 and sequentially stacked on the substrate 110. In other words, the organic scattering layer 122 is, for example, disposed between the substrate 110 and the first electrode layer 130, and contacts the substrate 110 and the first electrode layer 130, respectively.

The organic light emitting layer 140 and the second electrode layer 150 are, for example, sequentially disposed on the first electrode layer 130, and the hole transport layer 142 is, for example, disposed between the first electrode layer 130 and the organic light emitting layer 140. The electron transport layer 144 and the electron injection layer 146 are sequentially disposed between the organic light emitting layer 140 and the second electrode layer 150, for example. According to an embodiment, a hole injection layer can be further disposed between the first electrode layer 130 and the hole transport layer 142. However, it is noted that the disposition of the hole injection layer, the hole transport layer 142, the electron transport layer 144, and the electron injection layer 146 is optional, in other words, these layers may be not disposed in the organic light emitting device 100.

Generally, in the organic light emitting device, as the refractive index of the electrode layer is usually higher than the refractive index of the substrate, the light emitted from the organic light emitting layer is likely to be totally reflected at the interface between the electrode layer and the substrate. According to the present embodiment, the organic scattering layer 122 is formed between the electrode layer 130 and the substrate 110, that is, the organic scattering layer 122 is sandwiched between the electrode layer 130 and the substrate 110. As such, the light emitted from the organic light emitting layer 140 can be prevented from being totally reflected at the interface between the electrode layer 130 and the substrate 110, so as to greatly increase the light extraction efficiency of the organic light emitting device 100.

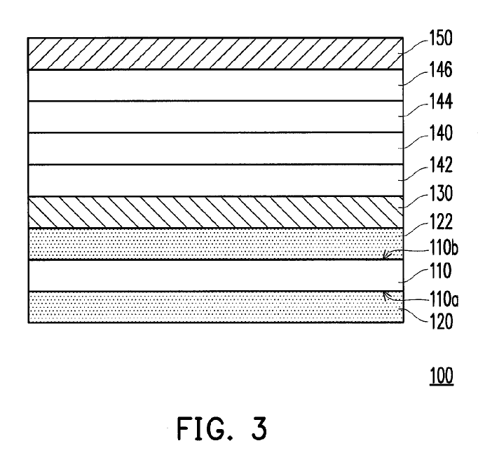

In the previous embodiments, the organic scattering layer 122 is disposed on the first surface 110a or the second surface 110b of the substrate 110, but the invention is not limited thereto. According to another embodiment, as shown in FIG. 3, the organic light emitting device 100 can include a first organic scattering layer 120 and a second organic scattering layer 122, wherein the first organic scattering layer 120 is disposed on the first surface 110a of the substrate 110, and the second organic scattering layer 122 is disposed on the second surface 110b of the substrate 110. In other words, according to the embodiment of FIG. 3, the first organic scattering layer 120 is disposed between the substrate 110 and the air, and the second organic scattering layer 122 is disposed between the substrate 110 and the first electrode layer 130. As such, the light emitted from the organic light emitting layer 140 can be prevented from being totally reflected at the interfaces between the substrate 110 and the air and between the electrode layer 130 and the substrate 110, so as to greatly increase the light extracting efficiency of the organic light emitting device 100.

The following describes an experimental embodiment to verify the effects described by the invention.

### EXPERIMENTAL EXAMPLE

In order to verify that the organic light emitting device according to the above embodiments has better device characteristics, experimental examples 1 to 4 are compared with a comparative example. The organic light emitting device according to the experimental examples 1 and 2 have a structure as shown in FIG. 1D, and the organic light emitting device according to the experimental examples 3 and 4 have a structure as shown in FIG. 2D. In the organic light emitting device according to the experimental examples 1 to 4, the substrate is a glass substrate, the material of the organic scattering layer is 4,7-diphenyl-1,10-phenanthroline (Bphen), the material of the first electrode layer is ITO, the material of the hole transport layer is N,N′-diphenyl-N,N′-bis(1-naphthyl)-(1,1′-biphenyl)-4,4′-diamine (NPB), the material of the organic light emitting layer is Tris(8-hydroxyquinolinato)aluminium (AlQ₃), the material of the electron transport layer is Tris(8-hydroxyquinolinato)aluminium (AlQ₃), the material of the electron injection layer is lithium fluoride (LiF), and the material of the second electrode layer is aluminum. The organic scattering layers according to the experimental examples 1 and 3 are formed by a vacuum evaporation process. The organic scattering layers according to the experimental examples 2 and 4 are formed by a coating method, which includes dissolving organic materials in methanol and then coating the formed solution onto the substrate by dropping. The structure of the organic light emitting device according to the comparative example is similar to the structure of the organic light emitting device according to the experimental examples 1 to 4, and the difference lies in that the organic light emitting device according to the comparative example doesn't have an organic scattering layer. That is, materials, thickness, and forming methods of other layers of the organic light emitting devices according to the experimental and comparative examples are the same.

As compared with the comparative example, the light extraction efficiencies of the organic light emitting devices according to the experimental examples 1 to 4 are respectively increased with 30%, 44%, 33% and 43% at the same driving power.

Therefore, according to the above results, it is known that, in the organic light emitting device, the disposition of the organic scattering layer between the substrate and the air or between the substrate and the electrode layer efficiently increases the light extraction efficiency of the organic light emitting device.

In view of the above, the organic light emitting device of the invention includes at least one organic scattering layer disposed on a surface of the substrate, and the organic scattering layer is, for example, disposed between the substrate and the air or between the substrate and the electrode layer. As such, the light emitted from the organic light emitting layer can be prevented from being totally reflected at the interfaces between the substrate and the air or between the electrode layer and the substrate, so as to greatly increase the light extraction efficiency of the organic light emitting device.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An organic light emitting device, comprising:
a substrate;
at least one organic scattering layer, disposed on a surface of the substrate, wherein a glass transition temperature Tg of a material of the organic scattering layer is lower than 150° C.;
a first electrode layer, disposed on the substrate;
an organic light emitting layer, disposed on the first electrode layer; and
a second electrode layer, disposed on the organic light emitting layer.

2. The organic light emitting device as claimed in claim 1, wherein an absorption wavelength of the material of the organic scattering layer is smaller than 400 nm.

3. The organic light emitting device as claimed in claim 1, wherein the material of the organic scattering layer comprises phenanthroline.

4. The organic light emitting device as claimed in claim 3, wherein the material of the organic scattering layer comprises 4,7-diphenyl-1,10-phenanthroline (Bphen) or 2,9-dimethyl-4,7-diphenyl-1,10-phenanthroline (BCP).

5. The organic light emitting device as claimed in claim 3, wherein the material of the organic scattering layer has a structure represented by Formula 1, and Z in Formula 1 is selective from the group consisting of Formula 2 to Formula 7.

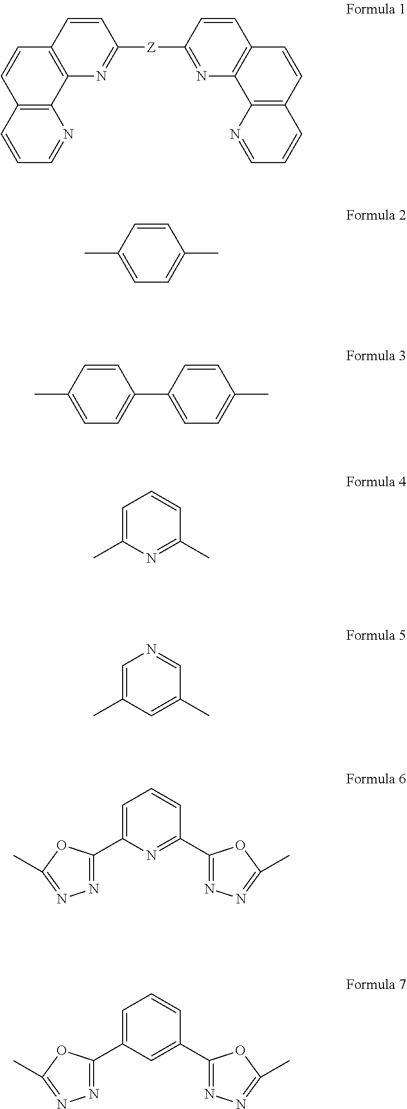

6. The organic light emitting device as claimed in claim 1, wherein the substrate is disposed between the at least one organic scattering layer and the first electrode layer.

7. The organic light emitting device as claimed in claim 1, wherein the at least one organic scattering layer is disposed between the substrate and the first electrode layer.

8. The organic light emitting device as claimed in claim 1, wherein the at least one organic scattering layer comprises a first organic scattering layer and a second organic scattering layer, and the first organic scattering layer and the second organic scattering layer are disposed on opposite surfaces of the substrate, respectively.

9. The organic light emitting device as claimed in claim 8, wherein the substrate is disposed between the first organic scattering layer and the first electrode layer, and the second organic scattering layer is disposed between the substrate and the first electrode layer.

10. The organic light emitting device as claimed in claim 1, further comprising:
a hole injection layer, disposed between the first electrode layer and the organic light emitting layer;
a hole transport layer, disposed between the first electrode layer and the organic light emitting layer;
an electron transport layer, disposed between the second electrode layer and the organic light emitting layer;
an electron injection layer, disposed between the second electrode layer and the organic light emitting layer.
